(19) United States
(12) Patent Application Publication
(10) Pub. No.: US 2012/0069513 A1
(43) Pub. Date: Mar. 22, 2012

(54) ELECTRONIC STORAGE MEDIUM

(76) Inventor: Arman Emami, Berlin (DE)

(21) Appl. No.: 13/322,601

(22) PCT Filed: May 26, 2010
(86) PCT No.: PCT/DE10/00590

§ 371 Date: Nov. 28, 2011

(30) Foreign Application Priority Data
May 27, 2009 (DE) 10 2009 022 787.3
Sep. 15, 2009 (DE) 10 2009 041 108.9
Feb. 16, 2010 (DE) 10 2010 008 632.0

(51) Int. Cl. G06F 1/16; H05K 13/00

(52) U.S. Cl. 361/679.32; 29/592.1

(57) ABSTRACT

A flat electronic storage medium, in particular a USB stick, which has a surface (A) made of elastic material, out of which a tongue-shaped partial surface (B) can be pushed out such that a carrier material (D) can be clamped between the total surface (A) and the partial surface (B). Instead of the partial surface, a wire (E) or a small plate (F) may be provided. It is further proposed that surfaces or partial surfaces, which during clamping of the carrier material (D) are directed at the carrier material (D), have a structured surface (G). In order to achieve an optimal clamping effect and deform the carrier material (D) as little as possible, the surface (B) that can be pushed out is designed sunken as compared to the surface (A). The sunken surface (B) preferably runs in parallel to the plane of the surface (A).

The invention relates to an electronic storage medium, in particular a USB stick which can be fixed to a base, such as note paper or business cards, in a way similar to a paper clip, as well as to a method for its manufacture.

Due to technical advance, the electronic storage media, in particular USB sticks, become continuously smaller in production and cheaper in price. The effect of this is that such data carriers are increasingly used for filing and for the transmission of the information to a third party. The reduction of volume of such data carriers does, however, simultaneously create the risk that the same cannot easily be found and/or are not immediately perceived or even get lost during transportation, transmission or filing.

Therefore, it is the object of the invention to design a data carrier, in particular a USB stick which can easily be fixed to a base, such as note paper or business cards, folders or the like without increasing by means of additional structures the volume as well as the production costs of such a data carrier.

According to the invention, the object is accomplished through the features of claim 1. Advantageous embodiments are the subject-matter of the sub-claims. Claim 12 constitutes an advantageous method for the manufacture.

According to the invention, an electronic storage medium, in particular a USB stick is proposed that has a surface made of elastic material that is provided with at least one opening, with the opening defining at least a part in the total surface such that at least a partial surface is created which due to the elasticity of the material can be opened up when being pushed in and/or pushed out so that a carrier material can be clamped between the total surface and the partial surface, or which has an essentially U- or V-shaped wire or a small plate the free wire ends of which or one edge of the small plate being fixed to a flat section of the storage medium so that a carrier material can be clamped between the wire or the small plate and the flat section.

The “data carrier clips” according to the invention can be fixed to bases just owing to their shape without an interfering by additional structures and fixing devices with the desired flatness of the data carrier which is in most cases required for transportation. Thus, the data carriers remain as flat as possible and almost two-dimensional and can nevertheless be easily and conveniently fixed at the bases like a flat paper clip.

In an advantageous embodiment it is proposed that surfaces or partial surfaces which during clamping of the carrier material are directed at the carrier material have a structured surface.

Such surfaces or partial surfaces with a structured surface can be provided both on the stick surface and on the partial surface or the partial surfaces which can be opened up or at the wire or at the small plate. For the forming of such surfaces or partial surfaces the inner side of the partial surfaces that can be opened up or of the wire or of the small plate is preferably used, i.e. the side which is directed at the carrier material.

Roughnesses, flutes and/or dotted and/or line-shaped elevations and/or provided sunken surfaces have stood the test as structured surface. A further or additional embodiment of the structured surface is envisaged in wave-shaped partial surfaces, in wave-shaped wire legs of the wire or in wave-shaped small plates.

These structured surfaces can be placed onto or into the stick surface, the partial surfaces that can be opened up or the wire legs or the small plates both during manufacture and during a subsequent processing.

In another embodiment, the structured surface has adhesive properties. This can be accomplished by means of adhesive strips with a removable protecting foil.

In order to achieve an optimal clamping effect and deform the carrier material as little as possible, according to another advantageous embodiment the surface that can be pushed out or pushed in (surface that can be opened up) is designed sunken as compared to the stick surface. The sunken surface preferably runs in parallel to the plane of the stick surface.

Here, the degree of the sunken surface should be equal to or smaller than the height of the stick surface when the flatness of the storage medium is of particular importance.

When the sunken surface is provided with a structured surface that is directed at the clamped carrier material—which is not a must but is advantageous—the elevations of the structured surface of the sunken surface should project into the opening in the stick surface which is created by such sunken design.

If the use is contemplated for a thicker carrier material, the degree of the sunken surface can also be selected greater than the height of the stick surface.

It is essential for a good attachment of the stick to the carrier material that a pre-stress exists between the partial surfaces, the wire or the small plate and the remaining surface of the stick or that a pre-stress is generated for facilitating the pushing-in of the carrier material . This does in fact mean that with an embodiment with partial surfaces the same must be moved out from the stick level in order to facilitate the pushing-in of the carrier material which corresponds to an elastic deformation that results in a pre-stress. The actual clamping force is thus always greater than a clamping force which would correspond to a deformation by the height of the carrier material alone.

In an embodiment with wire or small plates, the same are to be fixed at the stick under pre-stress. Through the insertion of the carrier material an existing clamping force is then also further increased.

The invention is to be explained by means of some embodiments in which the following is shown:

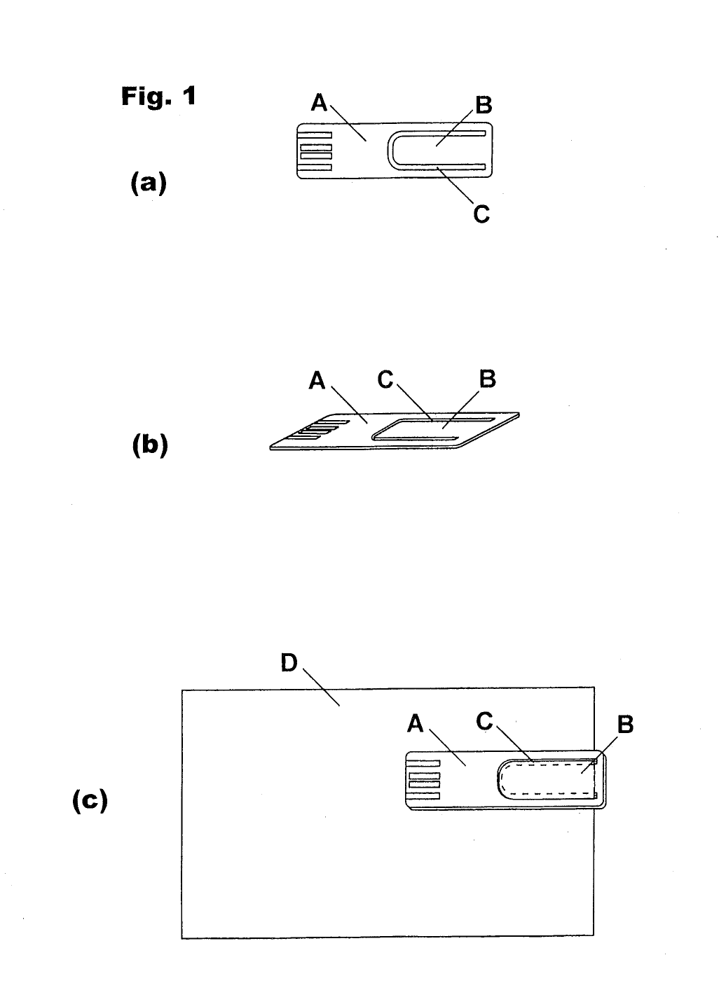

FIG. 1: USB stick with an inner opening,

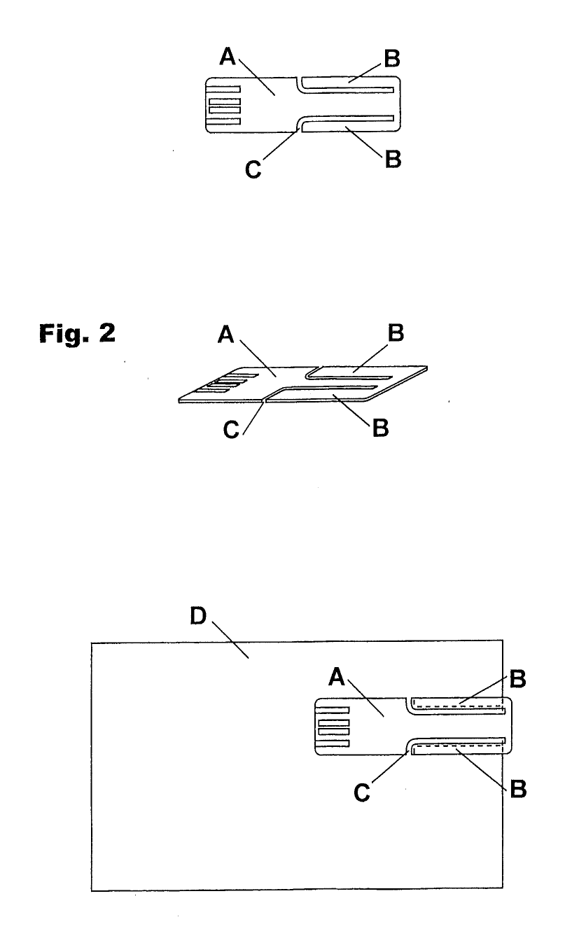

FIG. 2: USB stick with two openings,

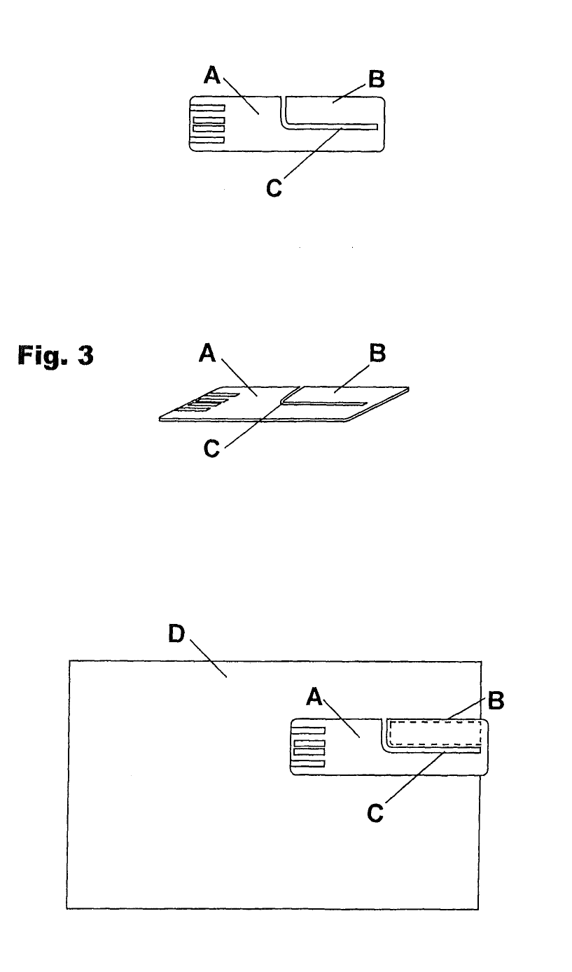

FIG. 3: USB stick with an L-shaped opening,

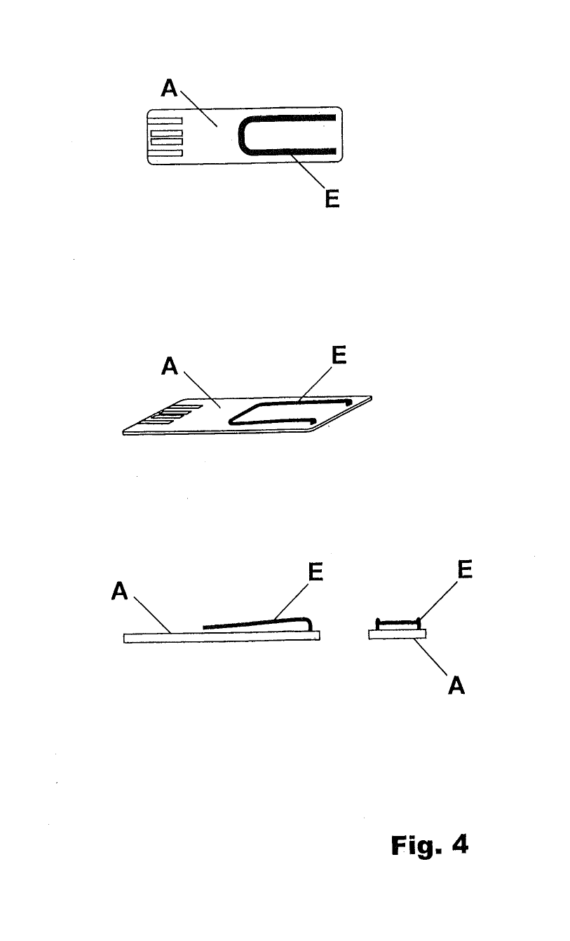

FIG. 4: USB stick with a wire bow,

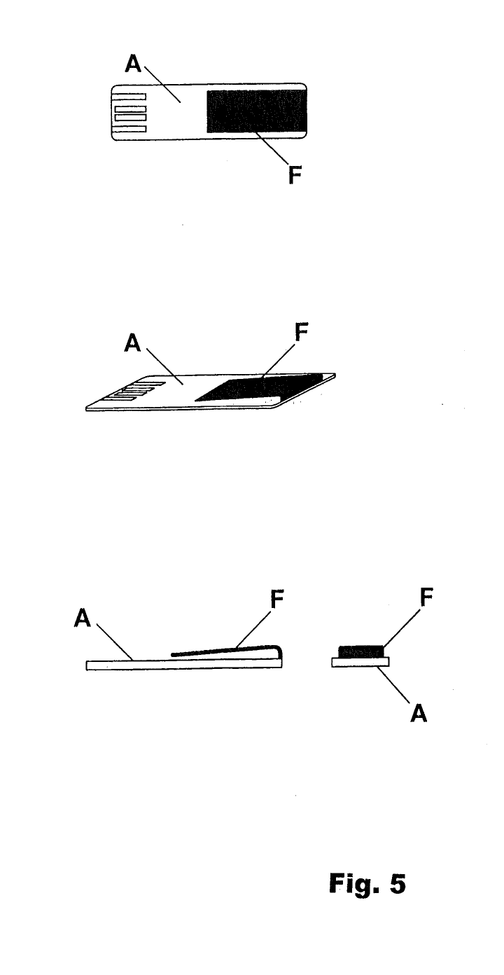

FIG. 5: USB stick with small plates,

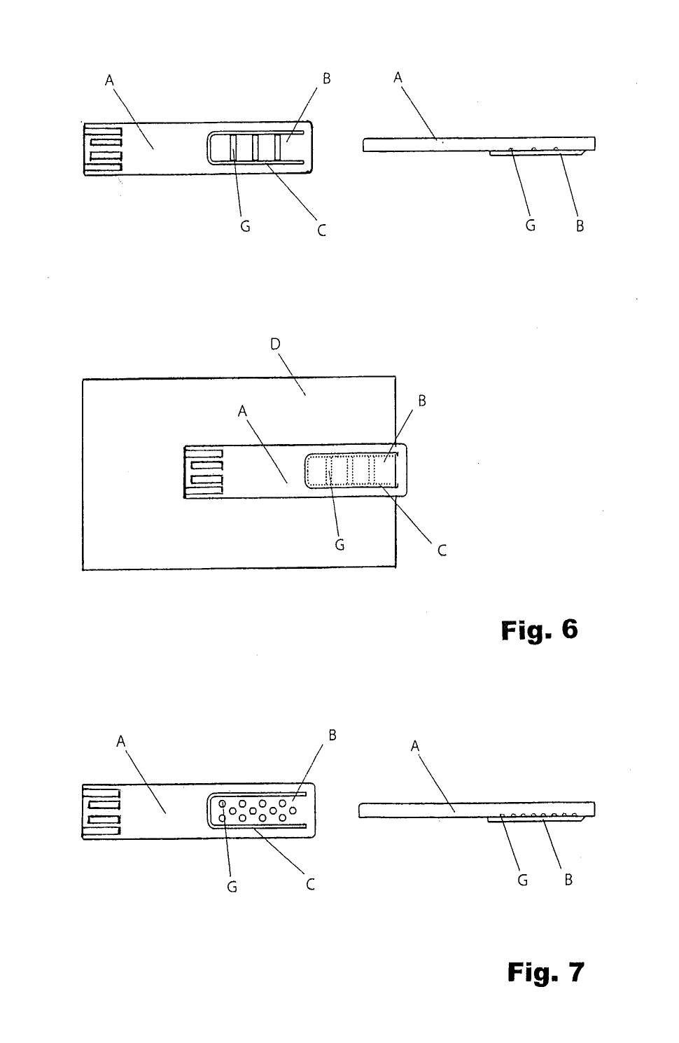

FIG. 6: USB stick with sunken surface and structured inner surface

FIG. 7: USB stick with sunken surface and flutes,

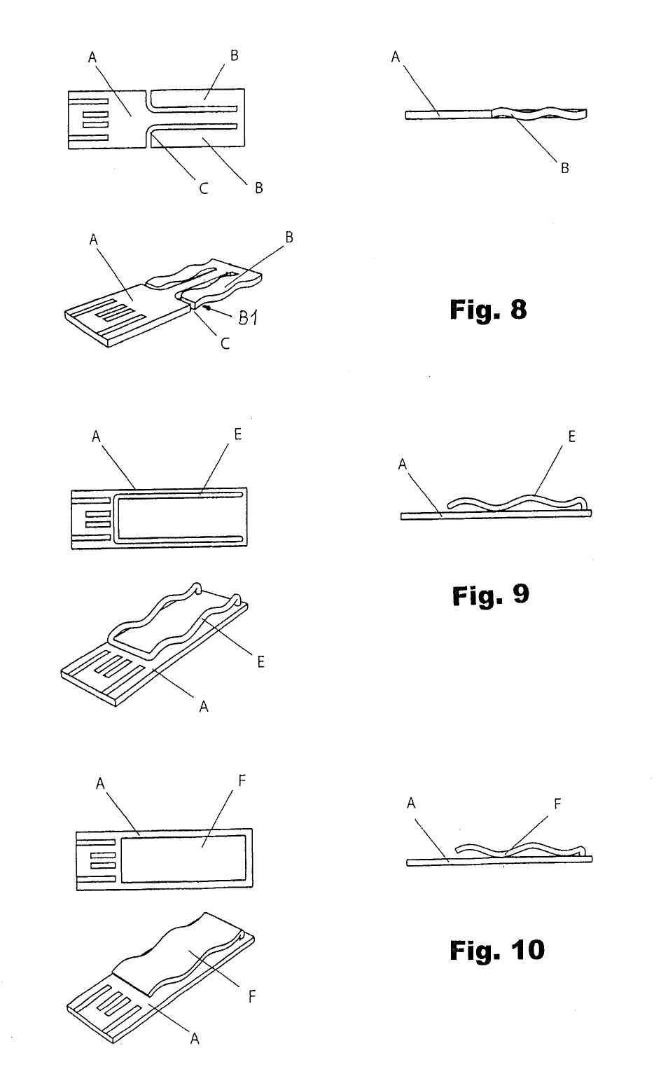

FIG. 8: USB stick with a wave-shaped surface,

FIG. 9: with wave-shaped wire for clamping and

FIG. 10: with wave-shaped small plates.

FIG. 1 shows a USB stick with a U-shaped opening (C) in surface (A) so that a surface (B) in the shape of a tongue that can be pushed out is formed. Surface (A) as used here has of course a height which is, however, comparatively small so that hereinafter reference will always be made only to a surface. If this surface (B) is pushed out, the USB stick can be clamped onto a flat carrier material.

According to FIG. 2 two openings (C) are provided in another embodiment each of which defines a partial surface (B) at the edge of the total surface (A). The flat carrier material (D) can be inserted between the two partial surfaces, on the one hand, and the total surface (A), on the other hand.

In the aforementioned two embodiments, the two partial surfaces (B) can be somewhat set off in relation to the total surface (A) such that the storage medium can be stuck also onto a somewhat thicker carrier material (D) without the partial surfaces sticking out from the carrier material (D). This objective can also be accomplished by having the partial surfaces (B) manufactured of a slightly thinner material than the total surface (A).

FIG. 3 shows a third embodiment which is provided with an essentially L-shaped opening (C) by means of which the partial surface (B) is defined in the total surface (A). A flat carrier material (D) can again be inserted between the said partial surface (B) and the total surface (A).

FIG. 4 shows a fourth embodiment which is provided with an essentially U- or V-shaped wire bow (E) which is fixed to the total surface (A) with its two free ends and runs essentially in parallel to the same. The fixing can be done for instance by inserting the two bent ends of the wire bow (E) into corresponding holes in the total surface (A). When doing so, the carrier material can be clamped between the bow (E) and the total surface (A).

According to FIG. 5, a fifth embodiment is provided which, has, instead of the bow of the embodiment having a wire, an essentially rectangular small plate (F) made of metal or plastic which is angle-shaped at one edge and is fixed with this edge at the total surface (A). This can, for instance, be done by insertion into a corresponding groove in the total surface (A) or by pasting or casting. In doing so, the small plate runs essentially in parallel to surface A and approaches surface A preferably with its free end. In this embodiment, too, the carrier material is clamped between the total surface (A) and the small plate (E).

It has become evident that a storage medium, as described above, deforms the carrier material during clamping, depending upon the surface and the strength of the carrier material, or may even slip off from the same. Therefore, advantageous designs of the aforementioned embodiments are described using the following figures.

In FIG. 6 surface (B) is designed somewhat sunken as compared to the plane of surface (A) being provided at the same time on the inner side with a structured surface (G) in the form of line-shaped elevations. The same exert a line-shaped pressure on the carrier material (D). The resiliency which results from the elasticity does not bring its force onto the surface of the carrier material (B) but only within the region of the line-shaped elevations, here, however, with a greater force which inter alia contributes to minimising the risk of slipping-off.

The elevations of the structured surface (G) of the sunken surface (B) may protrude into the opening in surface (A) created by means of the sunken design.

FIG. 7 shows a similar design. Surface (B) which can be pushed out from surface (A) for achieving the clamping effect is designed sunken as compared to surface (A). The sunken surface (B) runs in parallel to the plane of surface (A). The degree of the sunken surface is here equal to the height of surface(A) in order to preserve the flat shape of the USB stick. As a structured surface (G), surface (B) is provided with applied or inserted roughnesses. The same can be generated by pressing into the surface or also by applying a relevant coat or coat sections or graduated coats or directly during injection moulding.

FIG. 8 shows a USB stick embodiment with two openings (C) where the laterally arranged clamping tongues are designed as waved surfaces (B) in order to obtain a better adhesion on the carrier material (D). By the design of the free end (B1) of the clamping tongues being slightly directing away from surface (A), the carrier material can be more easily inserted between surfaces (B) and surface (A). The mentioned wave-shaped structuring can for instance also be generated by presses when the openings (C) are punched. The surfaces (B) can also be slightly sunken as compared to surface (A).

FIGS. 9 and 10 show embodiments where a wire (E) or a flat small plate (F) are used for achieving the clamping connection. They, too, have a wave shape in order to improve the adhesion of the USB stick on the carrier material (D).

Instead of or in addition to the wave-shaped design it is also proposed that the small plate (F) is provided with a structured surface (G) on the surface directing to the carrier material (D), for instance in the form or applied or inserted roughnesses, flutes and/or dotted and/or line-shaped elevations, the latter preferably running in parallel to the fixing edge of small plate (F).

The design deliberately does without sophisticated fixing devices as well as without additional components thus permitting a cost-effective production. Claim 12 constitutes an advantageous production method. Here, a production by punching is presented in addition to and as an alternative to the conventional injection moulding method. Here, the total surface of the data carrier (A) and the opening (C) that is required for clamping are punched out of a strong and elastic foil. The required electronic components, such as for instance the USB interface or storage unit are fixed on the foil before the punching, during punching or after punching by means of the known method, such as for instance pasting or pressing.

1. An electronic storage medium, in particular a USB stick,
(a) generally planar in shape, comprised of an elastic material, and having surface area (A) that is provided with at least one opening (C) defining within the total surface area (A) a partial surface area (B) which due to the elasticity of the material can be pushed in or pushed out from the generally planar shape so that a carrier material (D) can be clamped between the remainder of the total surface area (A) and the partial surface area (B), or
(b) comprising an essentially U- or V-shaped wire (E) or a small plate (F) the free ends of which in the case of a wire (E) or one edge of which in the case of a small plate (F) is/are fixed to a flat section (A) of the storage medium such that a carrier material (D) can be clamped between the wire (E) or the small plate (F) and the flat section (A).

2. The electronic storage medium according to claim 1, wherein the opening (C) is formed by a slot or a notch.

3. The electronic storage medium according to claim 1, wherein the surfaces or partial surfaces which when clamping the carrier material are directed at the carrier material (D) have a structured surface (G).

4. The An electronic storage medium according to claim 3, wherein the surfaces or partial surfaces are formed by the inner side of partial surface area (B) or of wire (E) or of the small plate (F).

5. The electronic storage medium according to claim 3, wherein the structured surface (G) is formed by roughnesses, flutes and/or dotted and/or line-shaped elevations and/or by provided sunken surfaces.

6. The electronic storage medium according to claim 3, wherein the structured surface (G) consists of wave-shaped partial surface areas (B) or in the case of wire (E) of wave-shaped wire legs or in the case of a small plate (F) of its wave-shaped form.

7. The electronic storage medium according to claim 3, wherein the structured surface (G) has adhesive properties.

8. The electronic storage medium according to claim 1, wherein the surface area (B) which can be pushed out from or pushed into the generally planar shape of surface area (A) for achieving the clamping effect is designed sunken as compared to surface area (A).

9. The electronic storage medium according to claim 8, wherein the sunken surface area (B) runs in parallel to the plane of surface area (A).

10. The electronic storage medium according to claim 8, wherein the degree of the sunken surface area (B) as compared to surface area (A) is equal to or smaller than the height of surface area (A) for thin carrier materials and even greater than the height of surface area (A) for thicker carrier materials (D).

11. The electronic storage medium according to claim 8, wherein elevations of the structured surface (G) of sunken surface area (B) project into the opening in surface area (A) that is created by the sunken design.

12. A method for the manufacture of an electronic storage medium, particular USB sticks, according to claim 1, wherein the total surface area (A) of the data carrier and its opening (C) are created by punching from a strong elastic foil and that the electronic components are fixed onto the foil by pasting and/or pressing before punching, during punching and/or after punching.

13. The method according to claim 12, wherein during punching of the openings (C) into surface area (A) and/or into surface area (B) which can be pushed out and each of which are directed at the carrier material (D), a structured surface is provided.
